(19) United States
(12) Patent Application Publication
(10) Pub. No.: US 2005/0275081 A1
(43) Pub. Date: Dec. 15, 2005

(54) Embedded chip semiconductor having dual electronic connection faces

(76) Inventor: Roger Chang, Lungtang Hsiang (TW)

Correspondence Address: DELLETT AND WALTERS, P. O. BOX 2786, PORTLAND, OR, 97208-2786, US

(21) Appl. No.: 10/866,292

(22) Filed: Jun. 12, 2004

(51) Int. Cl. H01L 23/48

(52) U.S. Cl. 257/690

(57) ABSTRACT

An embedded chip semiconductor has a substrate, at least one chip, an encapsulant, two circuit patterns and multiple contact vias. The substrate has a top surface, a bottom surface and at least one chip recess. The at least one chip has multiple terminals and is mounted in a corresponding chip recess. The thickness of the chip is equal to or less than the thickness of the substrate. The encapsulant is formed in the chip recess to hold the chip. The circuit patterns are respectively formed on the top and bottom surfaces of the substrate and one of the circuit patterns is connected to the multiple terminals of the chip. The two circuit patterns on two surfaces of the substrate are connected through the multiple contact vias. Therefore, the semiconductor has dual electronic connection faces to be suitable for different applications.

### BACKGROUND OF THE INVENTION

1. Field of the Invention

The present invention relates to a semiconductor package and more particularly to an embedded chip semiconductor fabricated with a printed circuit board fabrication process to form dual electronic connection faces.

2. Description of Related Art

With reference to FIG. 4, a conventional semiconductor package (50) comprises a leadframe (500), a chip (60) having I/O terminals (601), molded encapsulant (80) and wire bondings (70). The leadframe has a die pad (52) and multiple leads (51) around the die pad (52). A general process to package the semiconductor package (50) includes the following steps:

(a) mounting the chip (60) on the die pad (52) of the leadframe (500);

(b) connecting the I/O terminals (601) of the chip (60) to the leads (51) of the leadframe (500) by the wire bondings (70); and

(c) encapsulating the chip (60), wire bondings (70) and portions of the leadframe (500) with molded encapsulant (80) to complete a single semiconductor product.

For mass production of the semiconductor package (50), steps (a), (b) and (c) are executed repeatedly. Therefore, the production rate of the semiconductor packages is limited by the conventional production process. Furthermore, the chip is always connected to the leads of the leadframe, which is positioned on one side of the chip by the conventional semiconductor package. Therefore, the conventional semiconductor has one electronic connection face. To use the conventional semiconductor package, the leads on one side of the conventional semiconductor package are soldered to an external circuit board. Therefore, the semiconductor is limited to one way of connecting to the external circuit board.

To overcome the shortcomings, the present invention provides an embedded chip semiconductor package fabricated with a printed circuit board fabrication process to mitigate or obviate the aforementioned problems.

### SUMMARY OF THE INVENTION

The main objective of the invention is to provide an embedded chip semiconductor package having dual electronic connection faces. The present invention is fabricated with a printed circuit board fabrication process to effectively increase the mass production and has different connection ways for connecting to an external circuit board or other electronic elements.

In the printed circuit board fabrication process, a board with multiple integrated substrates is fabricated to accommodate multiple embedded chip semiconductors. At least one chip recess is defined in each substrate to hold a chip in each chip recess. Insulation material, such as resin, is pressed into all the chip recesses to hold the chips in the chip recesses. A first circuit pattern and a second circuit pattern are respectively formed on two opposite surfaces of each substrate. Multiple conduct vias are formed through the insulation material to connect to the first and second circuit patterns. The second circuit pattern faces to the terminals of the chip and is connected to terminals so the second circuit pattern functions as leads of the semiconductor. Since the first circuit pattern is connected to the second circuit pattern through multiple conductive vias, the first circuit pattern can be a ground terminal or a heat sink. Therefore, the semiconductor has dual electronic connection faces.

Other objectives, advantages and novel features of the invention will become more apparent from the following detailed description when taken in conjunction with the accompanying drawings.

### BRIEF DESCRIPTION OF THE DRAWINGS

FIG. 1 is a side view in partial section of a first embodiment of an embedded chip semiconductor in accordance with the present invention;

FIG. 2 is a side view in partial section of a second embodiment of an embedded chip semiconductor in accordance with the present invention;

FIGS. 3A to 3H are side plan views in partial section of interim products of the first embodiment of the embedded chip semiconductor in FIG. 1 produced with a printed circuit board process; and

FIG. 4 is a side view in partial section of a conventional semiconductor package in accordance with the prior art.

### DETAILED DESCRIPTION OF THE PREFERRED EMBODIMENT

An embedded chip semiconductor in accordance with the present invention is fabricated with a printed circuit board fabrication process so the single embedded chip semiconductors can be mass-produced and has dual electronic connection faces.

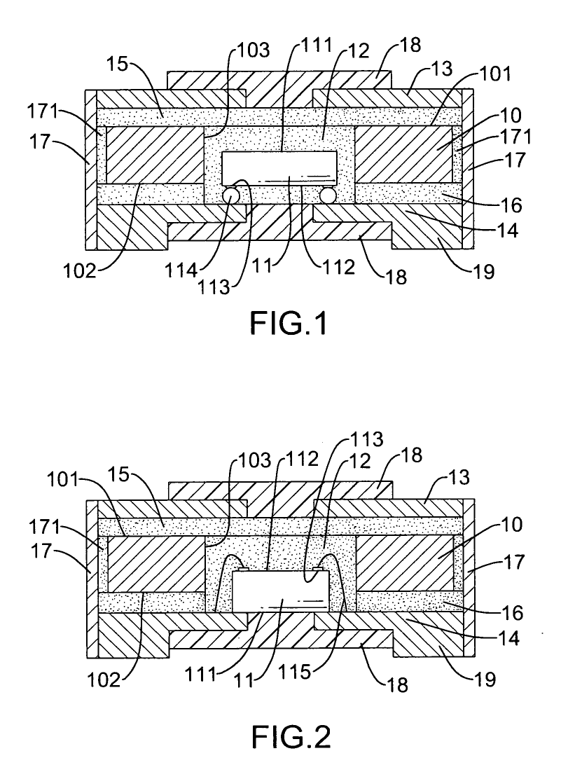

With reference to FIG. 1, a first embodiment of an embedded chip semiconductor in accordance with the present invention includes a substrate (10), at least one chip (11), an encapsulant (12), a first insulation layer (15), a second insulation layer (16), a first circuit pattern (13), a second circuit pattern (14), multiple conduct vias (17), multiple separations (171) and two optional protective layers (18).

The substrate (10) has a thickness (not numbered), a top surface (101), a bottom surface (102) and at least one chip recess (103). In the first embodiment, the substrate (10) is metallic. The substrate (10) is able to be nonmetallic.

Each chip (11) has a thickness (not numbered), a top face (111), a bottom face (112), outer edges (not numbered), multiple terminals (113) and solder bumps (114). The thickness of the chip (11) is equal to or less than the thickness of the substrate (10). The terminals (113) are formed on the bottom face (112). The solder bumps (114) are respectively connected to the corresponding terminals (113) of the chip (11).

The substrate (10) is metallic so the first insulation layer (15) is first formed on the top surface (101) and then the first circuit pattern (13) is formed on the first insulation layer (15) to insulate the first circuit pattern (13) from the substrate (10). If the substrate (10) is nonmetallic the first circuit pattern (13) can be directly formed on the top surface (101). The first circuit pattern (13) is made of copper.

A second insulation layer (16) is formed on the bottom surface (102) of the substrate (10). The second circuit pattern (14) is formed on the second insulation layer (16). The second circuit pattern (14) has an inner area and an outer area, and the terminals (113) on the chip (11) are connected to the inner area of the second circuit pattern (14) through the solder bumps (114). The inner area of the circuit pattern (14) corresponds to the chip recess (11), and the outer area is outside the inner area. The outer area is further extended outward to multiple bumps (19) as the leads of the semiconductor. If the substrate (10) is nonmetallic the second circuit pattern (14) can be directly formed on the bottom surface (101) of the substrate (10). The circuit pattern (14) is made of copper.

The encapsulant (13) is mainly formed in the chip recess (103) around the edges of the chip (11), the terminals (113) and the solder bumps (114) to insulate the chip (11) from the substrate (10).

The conduct vias (17) are respectively formed through the first insulation layer (15), the substrate (10) and the second insulation layer (16) to connect to the first and second circuit patterns (13, 14). Since the substrate (10) is metallic, each separation (171) is formed between a portion of each conduct via (17) corresponding to the substrate (10) to insulate the contact vias (17) and the metallic substrate (10).

The two protective layers (18) are respectively formed on portions of the first and second circuit patterns (13, 14).

With reference to FIG. 2, a second embodiment of the embedded chip semiconductor in accordance with the present invention is similar to the first embodiment, but the chip is held inversely in the chip recess. The terminals (113) of the chip (11) facing to the first circuit pattern (13) are connected to the second circuit pattern (14) through the wire bondings (115).

The present invention has a first circuit pattern (13) and a second circuit pattern (14). The second circuit pattern (14) can be mainly used to be the leads of the semiconductor and the first circuit pattern (13) can be used to be a ground terminal or a heat sink since the second circuit pattern (14) is connected to the first circuit pattern (13) through the contact vias (17). Therefore, the semiconductor has dual electronic connection faces.

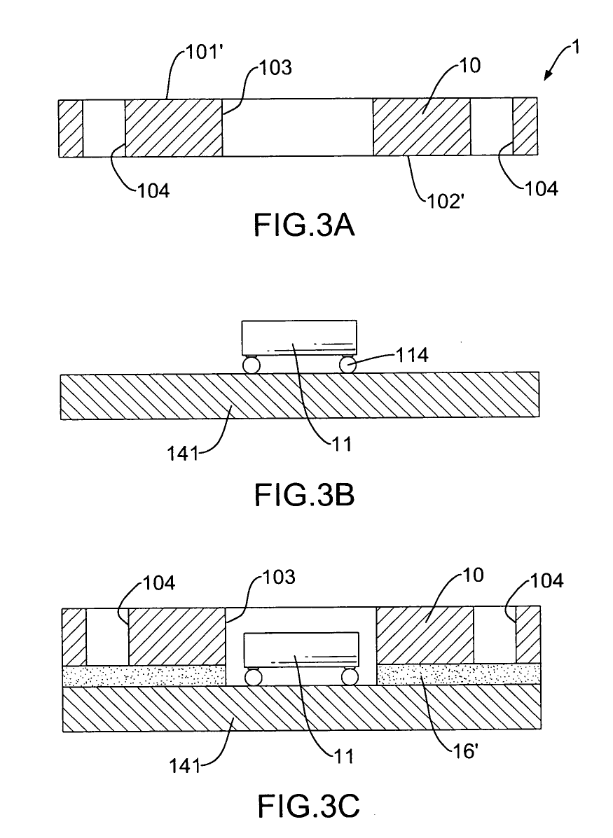

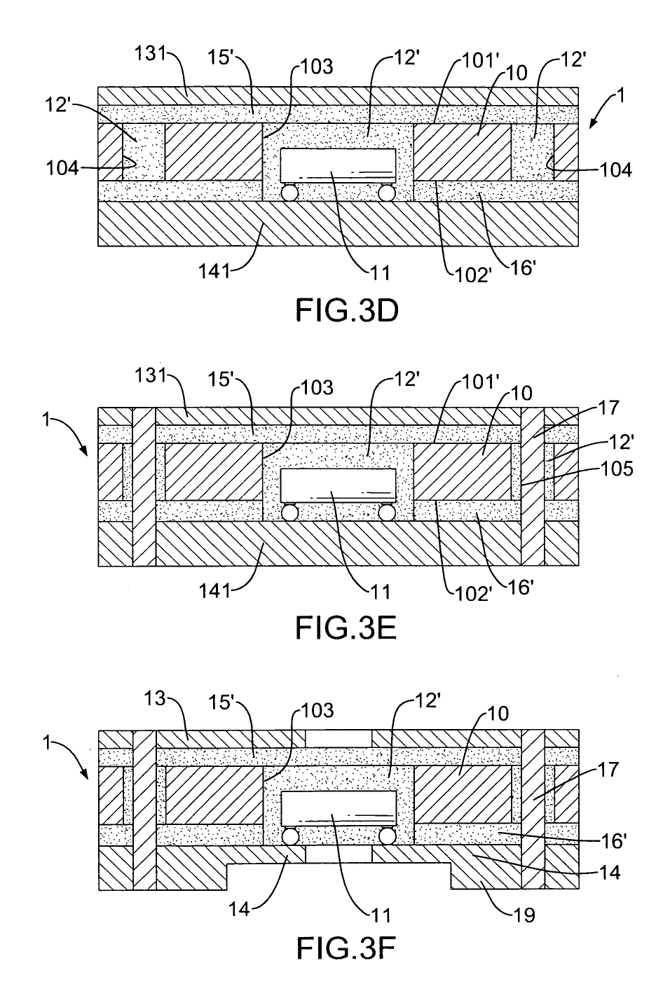

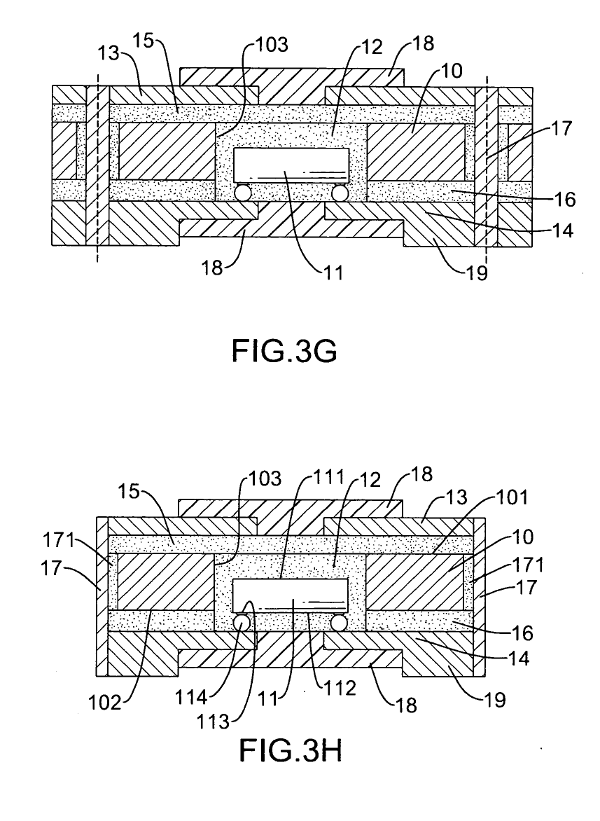

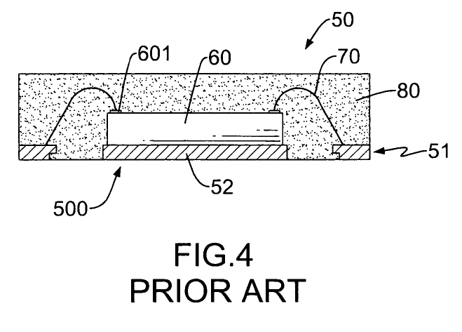

The present invention is fabricated with a printed circuit board fabrication process. With reference to FIGS. 3A to 3H, the printed circuit board fabrication process for fabricating the first embodiment has following steps of:

(a) Preparing a board (1) having a top side (101′), a bottom side (102′) and multiple substrates (10). At least one chip recess (103) and multiple through holes (104) are defined in each substrate (10) by an etching process or hole drilling process. The through holes (104) are positioned on boundaries of multiple substrates (10).

(b) Preparing a first copper plate (141) where multiple chips (11) with the solder bumps (114) are soldered.

(c) Attaching the board (1) to the first copper plate (141), wherein the bottom side (102′) of the board (1) with the insulation material (16′) is attached to the first copper plate (141). The insulation material (16′) is used as the second insulation layer (16). When the board (1) is attached to the first copper plate (141), the chip recesses (103) of the board (1) have to be aligned to face the positions where the chips (11) are positioned.

(d) Adding resin (12′, 15′) on a second copper plate (131).

(e) Vacuum pressing resin (12′, 15′) on the second copper plate (131) down to the top side (101′) of the board (1) to ensure the resin (12′, 15′) fills each chip recess (103) and the through holes (10), wherein the resin in the chip recess (103) is used as the encapsulant (12), the resin in the through hole (104) is used to the separation (171), and the resin in top side (101′) of the board (1) is as to the first insulation layer (15).

(f) Drilling holes (105), each of which is formed sequentially through the second copper plate (131), the resin (15′, 12′) on the top side (101′) and the through hole (104), the insulation material (16′) and the first copper plate (141).

(g) Electroplating peripheries defining the holes (105) to form the contact vias (17).

(h) Transforming the first and second copper plates respectively to a first and a second circuit patterns (13, 14) by image transfer process, development process, etching process etc. The second circuit pattern (14) has multiple bumps (19).

(i) Forming two protective layers (18) on portions of the first and second circuit patterns (13, 14).

(j) Separating each substrate (10) from the board (1). Since the contact vias (17) are positioned on boundaries of the multiple substrates so the board (1) is cut along the contact vias (17) to separate the multiple substrate (10). Each substrate (10) has been packaged to a signal semiconductor product.

The structure of the embedded chip semiconductor as described allows the embedded chip semiconductors to be mass-produced with a high-yield printed circuit board fabrication process. Each embedded chip semiconductor has dual electronic connection faces so the semiconductor can be used in different applications. That is, the two opposite faces of the semiconductor can be connected to an external circuit board or electronic elements. Furthermore, one side is for mounting to the external circuit board and the other face can be a heat sink or be a ground terminal. Comparing the present invention and the conventional semiconductor, the present invention is suitable for use in different applications and can be mass produced easily by the printed circuit board process.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An embedded chip semiconductor having dual electronic connection faces, comprising:
a substrate separated from a print circuit board having a top surface, a bottom surface and at least one chip recess;
at least one chip mounted respectively in the at least one chip recess and having outer edges, a top face, a bottom face and multiple terminals formed on the bottom face;
a first circuit pattern and a second circuit pattern respectively formed on the top and bottom surfaces of the substrate, wherein
the first circuit pattern is higher than the top face of the at least one chip; and
the second circuit pattern and has an inner area corresponding to the at least one chip recess and an outer area outside the inner area, wherein the terminals on the at least one chip are connected to the second circuit pattern;
an encapsulant vacuum press laminated in the at least one chip recess around the edges of the at least one chip to insulate the chip from the substrate, and flush with the top surface of the substrate; and
multiple contact vias respectively formed through the substrate to connect to the first and the second circuit patterns.

2. The semiconductor as claimed in claim 1, wherein the top face of each one of the at least one chip faces to the first circuit pattern and the terminals of each one of the at least one chip are connected to the second circuit pattern through multiple solder bumps.

3. The semiconductor as claimed in claim 1, wherein the top face of each one of the at least one chip is mounted on the second circuit pattern and the terminals on the bottom face of each one of the at least one chip are connected to the second circuit pattern through multiple wire bondings.

4. The semiconductor as claimed in claim 2, wherein the substrate is metallic and the semiconductor further comprises:
a first insulation layer vacuum press laminated among the first circuit pattern, the top surface of the substrate and the encapsulant;
a second insulation layer formed between the second circuit pattern and the bottom surface of the substrate; and
multiple separations respectively vacuum press laminated between a portion of each contact via and the substrate, wherein each contact via is further formed through the first and second insulation layers to connect to the first and second circuit patterns.

5. The semiconductor as claimed in claim 3, wherein the substrate is metallic and the semiconductor further comprises:
a first insulation layer vacuum press laminated among the first circuit pattern, the top surface of the substrate and the encapsulant;
a second insulation layer formed between the second circuit pattern and the bottom surface of the substrate; and
multiple separations respectively vacuum press laminated between a portion of each contact via and the substrate, wherein each contact via is further formed through the first and second insulation layers to connect to the first and second circuit patterns.

6. The semiconductor as claimed in claim 4, further comprising two protective layers respectively formed on portions of the first and second circuit patterns.

7. The semiconductor as claimed in claim 5, further comprising two protective layers respectively formed on portions of the first and second circuit patterns.

8. The semiconductor as claimed in claim 6, wherein the outer area of the second circuit pattern is extended outward to form multiple bumps.

9. The semiconductor as claimed in claim 7, wherein the outer area of the second circuit pattern is extended outward to form multiple bumps.

10. The semiconductor as claimed in claim 2, wherein the substrate is nonmetallic.

11. The semiconductor as claimed in claim 3, wherein the substrate is nonmetallic.

12. The semiconductor as claimed in claim 1, wherein the second circuit pattern comprises multiple bottom bumps, that are formed by etching a bottom of the second circuit pattern.

13. The semiconductor as claimed in claim 12, wherein the bottom bumps are pillars.
